(19) United States
(12) Patent Application Publication
(10) Pub. No.: US 2024/0175927 A1
(43) Pub. Date: May 30, 2024

(54) METHOD FOR CALCULATING TERMINAL VOLTAGE OF LITHIUM BATTERY BASED ON ELECTROCHEMICAL MODEL, APPARATUS, AND MEDIUM

(71) Applicant: Shanghai Makesens Energy Storage Technology Co., Ltd., Shanghai (CN)

(72) Inventors: Mingchen JIANG, Shanghai (CN); Qian LI, Shanghai (CN); Liangchang WEI, Shanghai (CN); Danfei GU, Shanghai (CN); Siyuan CHEN, Shanghai (CN); Xiao YAN, Shanghai (CN); Enhai ZHAO, Shanghai (CN)

(73) Assignee: Shanghai Makesens Energy Storage Technology Co., Ltd., Shanghai (CN)

(21) Appl. No.: 18/520,577

(22) Filed: Nov. 28, 2023

(30) Foreign Application Priority Data
Nov. 29, 2022 (CN) 202211516102X

(51) Int. Cl. G01R 31/367; G01R 31/3842

(52) U.S. Cl. CPC G01R 31/367; G01R 31/3842

(57) ABSTRACT

A method for calculating a terminal voltage of a lithium battery based on an electrochemical model, an apparatus, and a medium are provided. The method includes: constructing the electrochemical model of the lithium battery, and dividing the lithium-ion battery into three domains comprising an anode domain, a separator domain, and a cathode domain; numerically simulating the electrochemical model in the three domains respectively using the Chebyshev spectral method, and respectively obtaining distribution data of a liquid-phase potential, overpotential, and open-circuit voltage of the anode and the cathode; obtaining solid-phase potential distribution data of the anode and the cathode, based on discrete data of the liquid-phase potential, overpotential, and open-circuit voltage of the anode and the cathode; and obtaining the terminal voltage of the lithium battery based on the solid-phase potential distribution data of the anode and cathode. The present disclosure has high calculation accuracy and fast calculation speed.

### CROSS REFERENCE TO RELATED APPLICATION

The present application claims the benefit of priority to Chinese Patent Application No. 202211516102.X, entitled “METHOD FOR CALCULATING TERMINAL VOLTAGE OF LITHIUM BATTERY BASED ON ELECTROCHEMICAL MODEL, APPARATUS, AND MEDIUM”, filed with CNIPA on Nov. 29, 2022, the disclosure of which is incorporated herein by reference in its entirety for all purposes.

### FIELD OF TECHNOLOGY

The present disclosure generally relates to the technical field of lithium battery, and in particular relates to a method, apparatus and medium for calculating a terminal voltage of a lithium battery based on an electrochemical model.

### BACKGROUND

Under the global backdrop of “carbon neutrality”, the enthusiasm for finding clean energy that can replace petroleum energy continues to heat up. Solar energy, tidal energy, wind energy, hydropower, etc. are clean and sustainable energy sources, but the controllability of the origins of these energy sources is relatively weak. Lithium-ion batteries, the new generation of rechargeable batteries, are known for their high energy density and long cycle life. They are widely used in various fields such as mobile communication, digital technology, electric vehicles, energy storage, etc. The potential demand for lithium-ion batteries and their materials in the future is vast, indicating a massive market for the associated upstream and downstream industries. Establishing a physicochemical model for lithium-ion batteries, and obtaining simulated numerical values of physicochemical state variables in the spatiotemporal domain within the battery, can provide a clearer understanding of and facilitate monitoring of the real-time operational status of lithium-ion batteries. This, in turn, enhances the economic viability, reliability, and safety of lithium-ion batteries.

In electrochemical models, changes of most physicochemical state variables over time and space are described by partial differential equations in the temporal domain. These partial differential equations are described in both the temporal and spatial domains, necessitating attention to the separation of time and space. Also, some of the partial differential equations are strongly coupled to each other, and therefore, when conducting numerical simulations, it is necessary to decouple these equations. In an electrochemical quasi-two-dimensional coupled model, its equations are described in a one-dimensional Euclidean space, where each point of the one-dimensional Euclidean space is wrapped with a radius dimension of a datum at this point. In the coupling of these two spatial dimensions in the electrochemical quasi-two-dimensional model, various fields such as electric field, thermal field, and stress field are interconnected. This coupling represents a multitude of physicochemical processes comprising electrochemical reactions, mass transport, heat transfer, momentum transfer, and involves different phases and sub-phases such as particles, solids, liquids, metals, and polymers. At present, simulations of electrochemical models are mostly based on computing software such as Ansys, COMSOL, and Fluent, and there are few electrochemical models built from numerical simulation principles.

At present, mainstream methods for simulating electrochemical models comprise the finite difference method, the finite element method, the finite volume method, the fitting-function method, and methods of simplifying physicochemical control conditions. The finite difference method, the finite element method, and the finite volume method are discrete iterative solutions, and they impose high computational power requirements on the computing end, and the calculations are slow. This makes them unsuitable for high-throughput electrochemical calculations involving multiple batteries. The fitting-function method, and the methods of simplifying physicochemical control conditions only provide approximate and simplified solutions to the control equation. As a result, their accuracy is not high, which could lead to cumulative errors in practical applications.

As a result, the Euler method is currently the best approach for calculating the terminal voltage of lithium batteries, but it also could result in lower accuracy in numerical simulations.

### SUMMARY

A first embodiment of the present disclosure provides a method for calculating a terminal voltage of a lithium battery based on an electrochemical model, wherein the method comprises: S1: constructing the electrochemical model of the lithium battery, and dividing the lithium-ion battery into three domains comprising an anode domain, a separator domain, and a cathode domain, wherein the three domains respectively correspond to an anode, a separator and a cathode of the lithium battery; S2: numerically simulating the electrochemical model in the three domains respectively using the Chebyshev spectral method, and respectively obtaining distribution data of a liquid-phase potential, overpotential, and open-circuit voltage of the anode and the cathode; S3: obtaining solid-phase potential distribution data of the anode and the cathode, based on discrete data of the liquid-phase potential, overpotential, and open-circuit voltage of the anode and the cathode; and S4: obtaining the terminal voltage of the lithium battery based on the solid-phase potential distribution data of the anode and cathode.

A second embodiment of the present disclosure provides an apparatus for calculating a terminal voltage of a lithium battery based on an electrochemical model, comprising: a memory, on which a computer program is stored; and a processor, configured to call the computer program to perform the method for calculating the terminal voltage of the lithium battery based on the electrochemical model.

A third embodiment of the present disclosure provides a non-transitory computer-readable storage medium, storing a computer program, wherein the computer program is executed to implement the method for calculating the terminal voltage of the lithium battery based on the electrochemical model.

### BRIEF DESCRIPTION OF THE DRAWINGS

FIG. 1 shows a schematic diagram illustrating an architecture of a simulation calculation system according to an embodiment of the present disclosure.

FIG. 2 shows a flowchart illustrating a method for calculating a terminal voltage of a lithium battery based on an electrochemical model according to an embodiment of the present disclosure.

FIG. 3 is a schematic diagram showing constructing Chebyshev points according to an embodiment of the present disclosure.

FIG. 4 shows a schematic diagram illustrating domains of a lithium battery according to an embodiment of the present disclosure.

FIG. 5 shows a schematic diagram illustrating the distribution of Chebyshev points in each domain of the lithium battery according to an embodiment of the present disclosure.

FIG. 6 is a block diagram of a system for calculating a terminal voltage of a lithium battery according to an embodiment of the present disclosure.

FIG. 7 is a block diagram of an apparatus for calculating a terminal voltage of a lithium battery based on an electrochemical model according to an embodiment of the present disclosure.

### REFERENCE NUMERALS

11 Terminal
12 Server
41 Cathode domain
42 Separator domain
43 Anode domain
6 System for calculating a terminal voltage of a lithium battery
61 Model construction and domain division module
62 Simulation module
63 First calculation module
64 Second calculation module
7 Apparatus for calculating a terminal voltage of a lithium battery
71 Memory
72 Processor
S1˜S4 Various steps

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different specific embodiments. Various details in this specification can also be modified or changed based on different viewpoints and disclosures without departing from the spirit of the present disclosure. It should be noted that the following embodiments and the features of the following embodiments can be combined with each other if no conflict will result.

It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the layout of the components can also be more complicated.

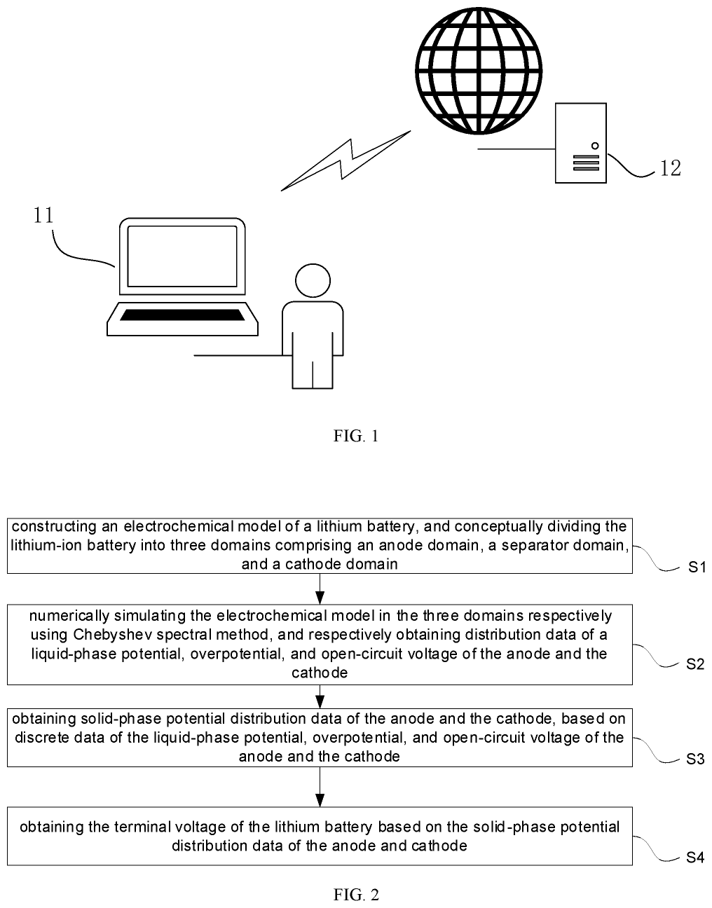

The present disclosure provides a method, apparatus, and medium for calculating a terminal voltage of a lithium battery based on an electrochemical model, which is applicable to a simulation calculation system shown in FIG. 1. As shown in FIG. 1, the simulation computing system comprises a terminal 11 and a server 12. The terminal 11 receives human-machine interaction data and sends simulation computing requests to the server 12. The server 12 performs simulation computing based on the simulation computing requests from the terminal 11. After completing the simulation computing, the server 12 sends the results to the terminal 11, where they are displayed. During the calculation of the terminal voltage of the lithium battery based on the electrochemical model, the terminal 11 is used to configure lithium battery parameters. The calculation comprises specifying parameters such as the size of a lithium battery, solid-phase, and liquid-phase material parameters, etc. The user generates the simulation computing requests in terminal 11 and sends them to the server 12. The server 12 then executes the method for calculating the terminal voltage of the lithium battery based on the electrochemical model.

The server described in the present disclosure is a type of computer that operates faster, handles higher loads, and typically comes at a higher price compared to regular computers. The server, in a network, provides computing or application services to other client machines, such as personal computers, smart phones, automatic teller machines, and even large-scale apparatuses like train systems. Servers are equipped with high-speed CPU processing power, ensuring reliable operation over extended periods. They also boast robust I/O capabilities for handling external data and offer superior scalability.

The terminal described in the present disclosure can be a mobile terminal or a fixed terminal, comprising but not limited to tablets, portable notebooks, personal computers, in-car systems, and more. Any apparatus with wireless communication, data processing, and display capabilities can be used to implement the technical solutions described in the present disclosure. Therefore, the scope of the present disclosure is not limited to the specific structure of the terminal as shown in FIG. 1.

The technical solutions of the present disclosure will be described in detail below in conjunction with the accompanying drawings.

As shown in FIG. 2, the method for calculating the terminal voltage of the lithium battery comprises steps S1 to S4.

Step S1: constructing the electrochemical model of the lithium battery, and dividing the lithium-ion battery into three domains comprising an anode domain, a separator domain, and a cathode domain, wherein the three domains respectively correspond to an anode, a separator, and a cathode of the lithium battery.

Step S2: numerically simulating the electrochemical model in the three domains respectively using the Chebyshev spectral method, and obtaining discrete distribution data of a liquid-phase potential, overpotential, and open-circuit voltage of the anode and the cathode of the lithium battery respectively.

Step S3: obtaining solid-phase potential distribution data of the anode and the cathode of the lithium battery, based on discrete data of the liquid-phase potential, overpotential, and open-circuit voltage of the anode and the cathode of the lithium battery.

Step S4: obtaining the terminal voltage of the lithium battery based on the solid-phase potential distribution data of the anode and cathode of the lithium battery.

In the present disclosure, the Chebyshev spectral method is utilized for the numerical solution of partial differential equations during the simulation process. Spectral methods are a class of numerical techniques for solving partial differential equations that is both ancient and emerging. For a long time, the spectral methods were not widely used due to their requirements for large computational capacity until the advent of fast Fourier transforms in 1965, which injected new life into the spectral methods. To date, spectral methods, along with the finite difference method and the finite element method, have become three fundamental approaches for numerical solutions of partial differential equations. The greatest advantage of the spectral methods is its “infinite-order convergence,” meaning that if the solution to an original problem is sufficiently smooth, the convergence order of the spectral methods is infinite.

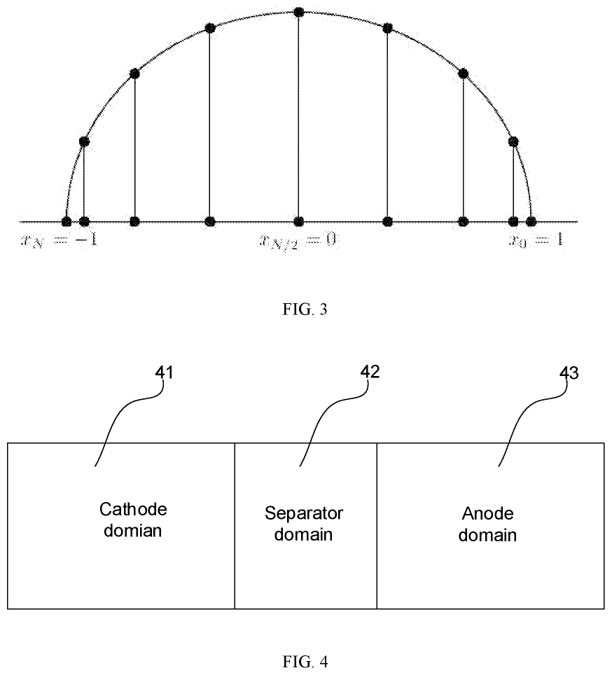

In the present disclosure, the Chebyshev spectral method offers the advantage of high computational accuracy at a relatively low computational cost while effectively avoiding the Gibbs phenomenon and Runge's phenomenon. The Chebyshev spectral method requires the construction of Chebyshev points. As illustrated in FIG. 3, the construction of Chebyshev points involves dividing the interval [−1, 1] into a grid, with a grid number of N, resulting in (N+1) Chebyshev points. The positions of these Chebyshev points are defined by the following formula:

xₖ=cos(kπ/N), k=0,1 . . . , N

The Chebyshev points can be understood as the locations on the x-axis where points from the upper half of a unit circle, evenly spaced and at equal angles, are projected. Taking N=8 as an example, the construction of Chebyshev points is illustrated in FIG. 3. It is worth noting that the Chebyshev points are sorted from right to left (from 1 to −1).

FIG. 4 shows areas of the lithium battery. It can be seen that the present disclosure divides the lithium battery into three to-be-computed domains, namely a cathode domain 41, a separator domain 42, and an anode domain 43. The Chebyshev spectral method is used for simulation calculations in the three domains of the lithium battery.

In one example, step S2 comprises Steps S21 and S22.

Step S21: numerically simulating the electrochemical model of the lithium-ion battery using the Chebyshev spectral method, where approximate values of physical quantities at Chebyshev points are obtained corresponding to one of the three to-be-computed domains, wherein the physical quantities in the anode domain and the cathode domain comprise liquid-phase exchange current density, liquid-phase lithium-ion concentration, overpotential, and open-circuit voltage, and the physical quantities in the separator domain comprise liquid-phase exchange current density and liquid-phase lithium-ion concentration.

The electrochemical model used in step S2 is a pseudo-two-dimensions (P2D) model for lithium batteries. The liquid-phase exchange current density, liquid-phase lithium-ion concentration, overpotential, and open-circuit voltage in the anode domain and the cathode domain, as well as the liquid-phase exchange current density and liquid-phase lithium-ion concentration in the separator domain can be obtained externally, thus obtaining approximations of each physical quantity at the Chebyshev points.

Step S22: solving a liquid-phase potential control equation in the electrochemical model in the to-be-computed domain using the Chebyshev spectral method, and obtaining approximate values of liquid-phase potential at the Chebyshev points corresponding to the to-be-computed domain, based on the liquid-phase exchange current density and liquid-phase lithium-ion concentration in the to-be-computed domain.

As an example, the three domains of the lithium battery have the same liquid-phase potential control equation, which is given by:

$$\frac{d {ϕ}_{e}}{d x} = - \frac{{i}_{e}}{{σ}^{eff}} + \frac{2 R T}{F} ( 1 - {t}_{c} ) \frac{d log {c}_{e}}{dx} ,$$

wherein, ϕₑ is the liquid-phase potential, iₑ is the liquid-phase exchange current density, cₑ is the liquid-phase lithium-ion concentration, σ^{eƒƒ} is a liquid-phase effective conductivity, R is the universal gas constant, Tis a reference temperature, F is the Faraday constant, t_{c} is the lithium-ion mobility, x is one of the spatial coordinate points in the to-be-computed domain.

As an example, step S22 comprises Steps S221-S225:

Step S221: constructing the Chebyshev points corresponding to the to-be-computed domain, and then mapping the spatial coordinate points from the to-be-computed domain to the Chebyshev computational interval.

Specifically, S221 comprises: dividing the Chebyshev computational interval [−1, 1] to obtain a grid with the Chebyshev grid number being N, and obtaining N+1 Chebyshev points, wherein the kth Chebyshev point is given by xₖ=cos(kπ/N), k=0,1 . . . , N; and

mapping the spatial coordinate points in the to-be-computed domain to the Chebyshev computational interval using the formula

$$X = \frac{2}{L} \cdot x - 1 ,$$

wherein, X is a coordinate point in the Chebyshev computational interval corresponding to x, and L is a length of the to-be-computed domain.

As an example, according to the length of each domain, different domains can be divided into grids with different grid numbers. For example, the anode domain and the cathode domain each may have a grid number of 8, and the separator domain may have a grid number of 3.

Step S222: transforming a solution interval of the liquid-phase potential control equation to the Chebyshev computational interval, wherein the transformed liquid-phase potential control equation is given by:

$$\frac{d {ϕ}_{e}}{dX} = - \frac{L \cdot i}{2 {σ}^{eff}} + \frac{2 RT}{F} ( 1 - {t}_{c} ) \frac{d log {c}_{e}}{dX} ;$$

Step S223: integrating the transformed liquid-phase potential control equation across each computational unit, whose result is given by:

$${ϕ}_{e} ( {x}_{j} ) - {ϕ}_{e} ( {x}_{j + 1} ) = - \frac{L}{2} {\int }_{{x}_{j + 1}}^{{x}_{j}} \frac{{i}_{e}}{{σ}^{eff}} dX + \frac{2 RT}{F} ( 1 - {t}_{c} ) ( log {c}_{e} ( {x}_{j} ) - log {c}_{e} ( {x}_{j + 1} ) ) ,$$

wherein [xⱼ₊₁, xⱼ] is a j-th computational unit of the Chebyshev computational interval, xⱼ and xⱼ₊₁ are two Chebyshev points of the j-th computational unit, j=1, 2, . . . , N, N is a Chebyshev grid number, ϕₑ(xⱼ) and ϕₑ(xⱼ₊₁) are approximate values of the liquid-phase potential at xⱼ and xⱼ₊₁;

Step S224: approximating as

$${\int }_{{x}_{j + 1}}^{{x}_{j}} \frac{{i}_{e}}{{σ}^{eff}} dX$$

as

$${\sum }_{k = 0}^{N} {A}_{jk} \frac{{i}_{e} ( {x}_{k} )}{{σ}^{eff} ( {x}_{k} )} ,$$

wherein xₖ is a kth Chebyshev point of the Chebyshev points corresponding to the to-be-computed domain, iₑ(xₖ) is an approximate value of the liquid exchange current density at the kth Chebyshev point, σ^{eƒƒ}(xₖ) is an approximate value of the liquid-phase effective conductivity at the kth Chebyshev point, and Aⱼₖ represents coefficients of the jth computational unit;

Step S225: obtaining an approximate value of the liquid potential at a first Chebyshev point at a starting position of the to-be-computed domain, calculating approximate values of the liquid potential at the two Chebyshev points of each computational unit based on:

$${ϕ}_{e} ( {x}_{j} ) - {ϕ}_{e} ( {x}_{j + 1} ) \approx {\sum }_{k = 0}^{N} {A}_{jk} \frac{{i}_{e} ( {x}_{k} )}{{σ}^{eff} ( {x}_{k} )} + \frac{2 RT}{F} ( 1 - {t}_{c} ) ( log {c}_{e} ( {x}_{j} ) - log {c}_{e} ( {x}_{j + 1} ) ) ;$$

and

obtaining approximate values of the liquid potential at the Chebyshev points corresponding to the to-be-computed domain.

The coefficients of the j-th computational unit are obtained by:

constructing a system of equations as follows:

$$\{ \begin{matrix}{\sum }_{k = 0}^{N} {A}_{jk} = {x}_{j} - {x}_{j + 1} \\ {\sum }_{k = 0}^{N} {A}_{jk} {x}_{k} = \frac{1}{2} ( {x}_{j}^{2} - {x}_{j + 1}^{2} ) \\ … \\ {\sum }_{k = 0}^{N} {A}_{jk} {x}_{k}^{N} = \frac{1}{N + 1} ( {x}_{j}^{N + 1} - {x}_{j + 1}^{N + 1} )\end{matrix} ,$$

wherein the above is a Vandermonde-type linear system of equations, and solving the system of equations to yield Aⱼₖ, wherein j=1, 2, . . . , N, k=0, 1, . . . , N. It should be noted that the coefficients are independent of the specific forms of iₑ and σ^{eƒƒ}. Therefore, the coefficients can be calculated in the initialization module of the numerical simulation. During the process of numerical simulation, when it is necessary to calculate the terminal voltage, the coefficients can be called directly. The grid number is N, so there are N computational units. Any j-th computational unit have a set of coefficients, k=0, 1, . . . , N, that is, each computational unit has a coefficient vector Aⱼ=[Aⱼ₀ Aⱼ₁, . . . A_{jN}]. For each to-be-computed domain, an N×(N+1) coefficient matrix is obtained.

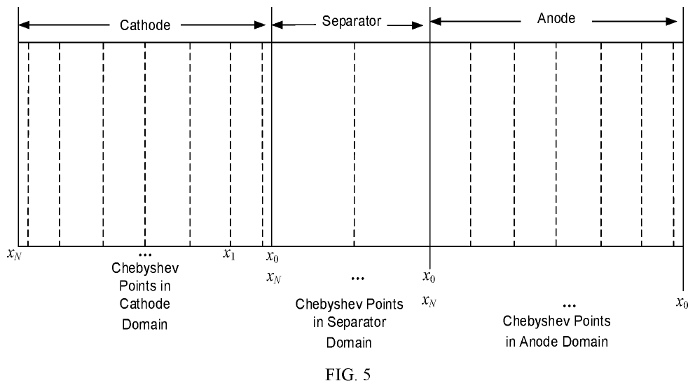

Specifically, as an example, the cathode domain of the lithium battery can be simulated first. Therefore, Chebyshev points are constructed for the cathode domain of the battery first. As shown in FIG. 5, in the calculation process, x_{N} is set as the zero-potential point, that is, let ϕₑ(x_{N})=0, and

$${ϕ}_{e} ( {x}_{j} ) - {ϕ}_{e} ( {x}_{j + 1} ) \approx {\sum }_{k = 0}^{N} {A}_{jk} \frac{{i}_{e} ( {x}_{k} )}{{σ}^{eff} ( {x}_{k} )} + \frac{2 RT}{F} ( 1 - {t}_{c} ) ( log {c}_{e} ( {x}_{j} ) - log {c}_{e} ( {x}_{j + 1} ) )$$

is used to calculate the liquid potential ϕₑ at each Chebyshev point in the cathode domain, wherein ϕₑ(x₀) is the liquid potential at the cathode/separator domain interface. Then, Chebyshev points are constructed for the separator domain of the lithium battery. The Chebyshev point x_{N} in the separator domain corresponds to the cathode/separator interface, that is, the Chebyshev point x_{N} in the separator domain corresponds to the Chebyshev point x₀ in the cathode domain. At this point, in the separator domain, ϕₑ(x_{N}) is known, and then the liquid potential ϕₑ at each Chebyshev point in the separator domain can be calculated. Finally, Chebyshev points are constructed for the anode domain of the lithium battery. The Chebyshev point x_{N} in the anode domain correspond to the anode/separator interface, that is, the Chebyshev point x_{N} in the anode domain corresponds to the Chebyshev point x₀ in the separator domain. At this point, in the anode domain, ϕₑ(x_{N}) is known, and then the liquid potential ϕₑ at each Chebyshev point in the anode domain can be calculated.

Step S3 comprises: for each of Chebyshev points corresponding to the cathode domain or the anode domain, obtaining an approximate value of a respective solid-phase potential using the formula ϕₛ=η+ϕₑ+ocν, wherein ϕₛ is the solid-phase potential, ϕₑ is the liquid-phase potential, η is the overpotential, and ocν is the open-circuit voltage at the terminal of the battery.

From the above process, it can be seen that η, ocν, and ϕₑ are all obtained through the Chebyshev spectral method, thereby obtaining the data of the Chebyshev ϕₛ discrete points, and then the numerical values of the solid-phase potential corresponding to each Chebyshev point in the anode domain and the cathode domain can be obtained.

Step S4 comprises: obtaining a first solid-phase potential ϕₛ⁺ at an interface between the anode and a current collector of the lithium battery, and a second solid-phase potential ϕₛ⁻ at an interface between the cathode and the current collector; calculating the terminal voltage Vₜₑᵣ of the lithium battery, which is given by Vₜₑᵣ=ϕₛ⁺−ϕₛ⁻. It should be noted that the first solid potential ϕₛ⁺ at the interface between the anode and the current collector and the second solid potential ϕₛ⁻ at the interface between the cathode and the current collector correspond to the approximate values of the solid potential at the Chebyshev points at the corresponding positions. That is, the Chebyshev point x_{N} in the cathode domain in FIG. 5 corresponds to the interface between the cathode and the current collector, the solid potential corresponding to the Chebyshev point x_{N} in the cathode domain is ϕₛ⁻; the Chebyshev point x₀ in the anode domain corresponds to the interface between the anode and the current collector, and the solid potential corresponding to the Chebyshev point x₀ in the anode domain is ϕₛ⁺.

In the present disclosure, the simulation of the electrochemical model is carried out through the Chebyshev spectral method, which greatly improves the simulation accuracy and realizes the accurate calculation of the terminal voltage of the lithium battery. At the same time, the calculation of the solid potential at the interface between the anode and the current collector, and the solid potential at the interface between the cathode and the current collector is realized through the recursive calculation of each domain, thereby realizing the accurate calculation of the terminal voltage of the lithium battery.

The scope of the method for calculating a terminal voltage of a lithium battery as described in the present disclosure is not limited to the sequence of operations listed. Any scheme realized by adding or subtracting operations or replacing operations of the traditional techniques according to the principle of the present disclosure is included in the scope of the present disclosure.

The present disclosure also provides a system for calculating a terminal voltage of a lithium battery, the system can implement the method for calculating a terminal voltage of a lithium battery described in the present disclosure, but systems for implementing the method of the present disclosure are not limited to the exact structure of the system as described in the present disclosure. Any structural adjustment or replacement of the prior art made according to the principles of the present disclosure is included in the scope of the present disclosure.

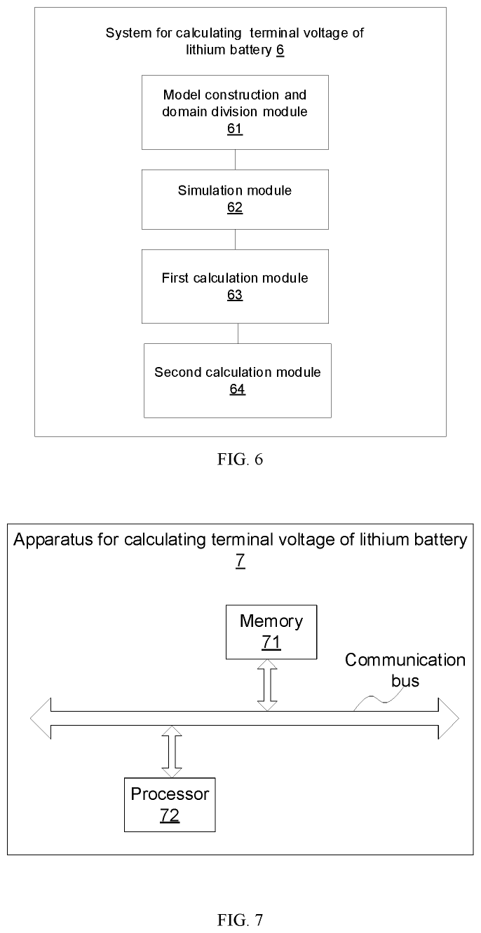

As shown in FIG. 6, the system 6 comprises:

a model construction and domain division module 61, which is configured to construct an electrochemical model of a lithium battery and divide the lithium-ion battery into three domains, comprising an anode domain, a separator domain, and a cathode domain, wherein the three domains respectively correspond to an anode, a separator, and a cathode of the lithium battery;

a simulation module 62, which is configured to numerically simulate the electrochemical model in the three domains respectively using the Chebyshev spectral method, and respectively obtain distribution data of a liquid-phase potential, overpotential, and open-circuit voltage of the anode and the cathode;

a first calculation module 63, which is configured to obtain solid-phase potential distribution data of the anode and the cathode, based on discrete data of the liquid-phase potential, overpotential, and open-circuit voltage of the anode and the cathode; and

a second calculation module 64, which is configured to obtain the terminal voltage of the lithium battery based on the solid-phase potential distribution data of the anode and cathode.

As shown in FIG. 7, the present disclosure further provides an apparatus for calculating a terminal voltage of a lithium battery based on an electrochemical model. The apparatus 7 comprises a memory 71 configured to store a computer program, a processor 72 configured to call the computer program to execute the method for calculating a terminal voltage of a lithium battery.

The memory 71 comprises one or more of a read-only memory (ROM), random access memory (RAM), magnetic disk, flash disk, memory card, optical disk, or other non-transitory medium that can store program codes.

Preferably, the processor 72 can be a general processor, comprising a central processing unit (CPU), a network processor (NP), etc. It can also be a digital signal processor (DSP) or an application specific integrated circuit (ASIC), a field programmable gate array (FPGA) or other programmable logic devices, discrete gates or transistor logic devices, discrete hardware components.

It should be understood that the system, apparatus, or method disclosed in the present disclosure can be implemented in alternative ways. For example, the apparatus embodiments described above are merely illustrative. For instance, the division of modules/units is just a logical functional division, and there may be other ways of division in actual implementation. For example, multiple modules or units can be combined or integrated into another system, or some features can be ignored or not executed. Furthermore, the coupling or direct coupling or communicative connection between two elements can be through some interfaces, the indirect coupling or communicative connection between apparatuses or modules or units can be electrical, mechanical, or in other forms.

The modules/units described herein as separate components can be physically separate or not, and the components shown as modules/units can be physical modules or not, that is, they can be located in one place, or they can be distributed on multiple networked units. Some or all of the modules/units may be selected according to actual needs to achieve the purpose of the present disclosure. For instance, for each functional module/unit of the present disclosure, it can be integrated into a processing module, or each module/unit can physically exist independently, or two or more modules/units can be integrated into one module/unit.

Those skilled in the art should further realize that the units and algorithm steps disclosed in the examples described in the present disclosure can be implemented with electronic hardware, computer software, or a combination of both. To clearly illustrate the interchangeability of hardware and software, the components and steps of each example have been generally described according to their functions in the above specification. Whether these functions are executed in hardware or software depends on the specific application and design constraints of the technical solution. Professionals can use different methods to implement the described functions for each specific application, and such implementations should not be considered beyond the scope of the present disclosure.

The present disclosure also provides a non-transitory computer-readable storage medium. A person of ordinary skill in the art would understand that all or some of the steps in the method of implementing the above embodiments can be accomplished by instructing a processor through a program that can be stored in the computer-readable storage medium that is a non-transitory medium, such as a RAM, ROM, flash memory, hard disk, solid-state disks (SSD), magnetic tape, floppy disk, optical disc, and any combination thereof. The above-mentioned storage medium can be any available medium that a computer can access, or it can be a data storage apparatus such as a server, a data center, etc., that integrates one or more available media. These available media can include magnetic media (e.g., floppy disks, hard disks, magnetic tapes), optical media (e.g., digital versatile disc (DVD)), or semiconductor media (e.g., SSD).

The embodiments of the present disclosure can also provide a computer program product comprising one or more computer instructions. When the computer instructions are loaded and executed on a computing device, they generate, either wholly or partially, the processes or functions described in the embodiments of the present disclosure. These computer instructions can be stored in a computer-readable storage medium or transferred from one computer-readable storage medium to another. For instance, the computer instructions can be transferred from one website, computer, or data center to another through wired means (such as coaxial cable, fiber optics, digital subscriber line (DSL)) or wireless means (such as infrared, wireless, microwave, etc.).

When the computer program product is executed by a computer, the computer performs the method described in the embodiments of the present disclosure. This computer program product can be in the form of a software installation package. In situations where the method described in the embodiments is needed, the computer program product can be downloaded and executed on a computer.

The descriptions of the processes or structures corresponding to the various figures may emphasize different embodiments. Parts not detailed in a particular process or structure can be referenced in the descriptions of other relevant processes or structures.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for calculating a terminal voltage of a lithium battery based on an electrochemical model, wherein the method comprises:
S1: constructing the electrochemical model of the lithium battery, and dividing the lithium-ion battery into three domains comprising an anode domain, a separator domain, and a cathode domain, wherein the three domains respectively represent an anode, a separator, and a cathode of the lithium battery;
S2: numerically simulating the electrochemical model in the three domains respectively using Chebyshev spectral method, and obtaining distribution data of a liquid-phase potential, overpotential, and open-circuit voltage of the anode and the cathode respectively;
S3: obtaining solid-phase potential distribution data of the anode and the cathode, based on discrete data of the liquid-phase potential, overpotential, and open-circuit voltage of the anode and the cathode of the lithium battery; and
S4: obtaining the terminal voltage of the lithium battery based on the solid-phase potential distribution data of the anode and cathode.

2. The method for calculating the terminal voltage of the lithium battery based on the electrochemical model according to claim 1, wherein the Chebyshev spectral method includes a plurality of Chebyshev points which relates to data in one of the domains in the lithium battery, and wherein S2 further comprises:
S21: numerically simulating the electrochemical model of the lithium-ion battery using the Chebyshev spectral method, where approximate values of physical quantities at the plurality of Chebyshev points in one of the domains are obtained; wherein the approximate values of the physical quantities in the anode domain and the cathode domain comprise liquid-phase exchange current density, liquid-phase lithium-ion concentration, overpotential, and open-circuit voltage, and the physical quantities in the separator domain comprise liquid-phase exchange current density and liquid-phase lithium-ion concentration; and
S22: solving a liquid-phase potential control equation in the electrochemical model in said domain by applying the Chebyshev spectral method, and obtaining approximate values of the liquid-phase potential at the plurality of Chebyshev points in said domain, based on the liquid-phase exchange current density and liquid-phase lithium-ion concentration in said domain.

3. The method for calculating the terminal voltage of the lithium battery based on the electrochemical model according to claim 2, wherein the three domains share the same liquid-phase potential control equation, which is given by:
$$\frac{d {ϕ}_{e}}{dX} = - \frac{{i}_{e}}{{σ}^{eff}} + \frac{2 RT}{F} ( 1 - {t}_{c} ) \frac{d log {c}_{e}}{dX} ,$$
wherein ϕₑ is liquid-phase potential, iₑ is liquid-phase exchange current density, cₑ is liquid-phase lithium-ion concentration, σ^{eƒƒ} is a liquid-phase effective conductivity, R is universal gas constant, T is a reference temperature, F is Faraday constant, t_{c} is a lithium-ion mobility, and x is one of spatial coordinate points in said domain.

4. The method for calculating the terminal voltage of the lithium battery based on the electrochemical model according to claim 3, wherein S22 further comprises:
S221: constructing the plurality of Chebyshev points of said domain, and then mapping the spatial coordinate points from said domain to a Chebyshev computational interval;
S222: transforming a solution interval of the liquid-phase potential control equation to the Chebyshev computational interval, wherein the transformed liquid-phase potential control equation is given by:
$$\frac{d {ϕ}_{e}}{dX} = - \frac{L \cdot {i}_{e}}{2 {σ}^{eff}} + \frac{2 RT}{F} ( 1 - {t}_{c} ) \frac{d log {c}_{e}}{dX} ,$$
wherein X is a coordinate point in the Chebyshev computational interval corresponding to x, and L is a length of said domain;
S223: integrating the transformed liquid-phase potential control equation across each computational unit, whose result is given by:
$${ϕ}_{e} ( {x}_{j} ) - {ϕ}_{e} ( {x}_{j + 1} ) = - \frac{L}{2} {\int }_{{x}_{j + 1}}^{{x}_{j}} \frac{{i}_{e}}{{σ}^{eff}} dX + \frac{2 RT}{F} ( 1 - {t}_{c} ) ( log {c}_{e} ( {x}_{j} ) - log {c}_{e} ( {x}_{j + 1} ) ) ,$$
wherein [xⱼ₊₁, xⱼ] is a j-th computational unit of the Chebyshev computational interval, xⱼ and xⱼ₊₁ are two Chebyshev points of the j-th computational unit, j=1, 2, . . . , N, N is a Chebyshev grid number, ϕₑ(xⱼ) and ϕₑ(xⱼ₊₁) are approximate values of the liquid-phase potential at xⱼ and xⱼ₊₁;
S224: approximating
$${\int }_{{x}_{j + 1}}^{{x}_{j}} \frac{{i}_{e}}{{σ}^{eff}} dX$$
as
$${\sum }_{k = 0}^{N} {A}_{jk} \frac{{i}_{e} ( {x}_{k} )}{{σ}^{eff} ( {x}_{k} )} ,$$
wherein xₖ is a kth Chebyshev point of the Chebyshev points corresponding to said domain, iₑ (xₖ) is an approximate value of the liquid exchange current density at the kth Chebyshev point, σ^{eƒƒ}(xₖ) is an approximate value of the liquid-phase effective conductivity at the kth Chebyshev point, and Aⱼₖ represents coefficients of the jth computational unit; and
S225: obtaining an approximate value of the liquid potential at a first Chebyshev point at a starting position of said domain, calculating the approximate values of the liquid potential at the two Chebyshev points of each computational unit based on:
$${ϕ}_{e} ( {x}_{j} ) - {ϕ}_{e} ( {x}_{j + 1} ) \approx {\sum }_{k = 0}^{N} {A}_{jk} \frac{{i}_{e} ( {x}_{k} )}{{σ}^{eff} ( {x}_{k} )} + \frac{2 RT}{F} ( 1 - {t}_{c} ) ( log {c}_{e} ( {x}_{j} ) - log {c}_{e} ( {x}_{j + 1} ) ) ;$$
and obtaining approximate values of the liquid potential at the Chebyshev points corresponding to said domain.

5. The method for calculating the terminal voltage of the lithium battery based on the electrochemical model according to claim 4, wherein S221 further comprises:
dividing a Chebyshev computational interval [−1, 1] to obtain a grid which has a Chebyshev grid number N, and obtaining N+1 Chebyshev points, wherein a k-th Chebyshev point is calculated by: xₖ=cos(kπ/N), k=0,1 . . . , N, and
mapping the spatial coordinate points in said domain to the Chebyshev computational interval using the formula
$$X = \frac{2}{L} \cdot x - 1.$$

6. The method for calculating the terminal voltage of the lithium battery based on the electrochemical model according to claim 4, wherein the coefficients of the jth computational unit are obtained by:
constructing a system of equations as follows:
$$\{ \begin{matrix}{\sum }_{k = 0}^{N} {A}_{jk} = {x}_{j} - {x}_{j + 1} \\ {\sum }_{k = 0}^{N} {A}_{jk} {x}_{k} = \frac{1}{2} ( {x}_{j}^{2} - {x}_{j + 1}^{2} ) \\ … \\ {\sum }_{k = 0}^{N} {A}_{jk} {x}_{k}^{N} = \frac{1}{N + 1} ( {x}_{j}^{N + 1} - {x}_{j + 1}^{N + 1} )\end{matrix} ,$$
solving the system of equations to yield Aⱼₖ, wherein j=1, 2, . . . , N, k=0, 1, . . . , N.

7. The method for calculating the terminal voltage of the lithium battery based on the electrochemical model according to claim 1, wherein S3 further comprises:
for each of the plurality of Chebyshev points in the cathode domain or the anode domain, obtaining an approximate value of a respective solid-phase potential using the formula ϕₛ=η+ϕₑ+ocν, wherein ϕₛ is the solid-phase potential, ϕₑ is the liquid-phase potential, η is the overpotential, and ocν is the open-circuit voltage at the terminal of the lithium battery.

8. The method for calculating the terminal voltage of the lithium battery based on the electrochemical model according to claim 1, wherein S4 further comprises:
obtaining a first solid-phase potential ϕₛ⁺ at an interface between the anode and a current collector of the lithium battery, and a second solid-phase potential ϕₛ⁻ at an interface between the cathode and the current collector; and
calculating the terminal voltage Vₜₑᵣ of the lithium battery, by calculating equation of Vₜₑᵣ=ϕₛ⁺−ϕₛ⁻.

9. An apparatus for calculating the terminal voltage of the lithium battery based on the electrochemical model, comprising:
a memory, on which a computer program is stored; and
a processor, configured to call the computer program to perform the method for calculating the terminal voltage of the lithium battery based on the electrochemical model according to claim 1.

10. A non-transitory computer-readable storage medium, storing a computer program, wherein the computer program is executed to implement the method for calculating the terminal voltage of the lithium battery based on the electrochemical model according to claim 1.
